(19) United States
(12) Patent Application Publication
(10) Pub. No.: US 2025/0285860 A1
(43) Pub. Date: Sep. 11, 2025

(54) METHOD FOR MANUFACTURING SEMICONDUCTOR TEMPLATE HAVING GROUP III METAL POLAR SURFACE

(71) Applicant: WAVELORD CO., LTD, Hwaseong-si (KR)

(72) Inventors: Juneo SONG, Suwon-si (KR); Hyeong Seon YUN, Paju-si (KR); Young Hun HAN, Osan-si (KR); Ji Hyung MOON, Gunpo-si (KR); Jin Hyoung CHO, Seongnam-si (KR)

(73) Assignee: WAVELORD CO., LTD, Hwaseong-si (KR)

(21) Appl. No.: 18/860,668

(22) PCT Filed: Mar. 13, 2024
(86) PCT No.: PCT/KR2024/003200

§ 371 Date: Oct. 27, 2024

(30) Foreign Application Priority Data
Mar. 14, 2023 (KR) 10-2023-0033378

(51) Int. Cl. H01L 21/02; C30B 25/18; C30B 29/40; C30B 33/00

(52) U.S. Cl. CPC H01L 21/0254; C30B 25/186; C30B 29/403; C30B 33/00; H01L 21/02381; H01L 21/0242

(57) ABSTRACT

The present invention pertains to a method for manufacturing a semiconductor template, in which a high-quality, highly crystalline Group III metal polar surface is obtained by performing a substrate bonding process only once by selectively growing AlxGa1-xN materials having different polarities on a nominal on-axis c-plane sapphire substrate or Si(111) initial growth substrate without using an expensive off-angle sapphire substrate.

### TECHNICAL FIELD

The present invention relates to a method of manufacturing a semiconductor template having a group III metal polar surface, and more specifically, to a method of manufacturing a high-quality semiconductor template having a group III metal polar surface, which has excellent crystallinity, using only a one-step substrate bonding process.

### BACKGROUND ART

Unlike SiC semiconductor devices (metal-oxide-semiconductor field effect transistors (MOSFETs) or diodes) designed and manufactured after being grown on the conventional homogeneous single crystalline SiC initial growth substrate (wafer), group III nitride semiconductor devices are designed and manufactured by epitaxially growing a group III nitride semiconductor directly on a heterogeneous large-diameter (6 inches or more) single crystalline sapphire or an Si initial growth substrate due to the absence of low-cost commercial single crystalline GaN or AlN initial growth substrate, and a semiconductor template (initial growth substrate wafer) having a seed layer with a group III nitride metal polar surface has recently been researched and developed to further improve the quality and performance of the group III nitride semiconductor devices.

FIG. 1 shows a process of manufacturing a semiconductor template having a group III metal polar surface through the conventional two-step substrate bonding process, and FIG. 2 shows a process of manufacturing a semiconductor template having a group III metal polar surface through the conventional one-step substrate bonding process.

As shown in FIG. 1, in the conventional two-step substrate bonding process, a semiconductor template having a group III nitride metal polar surface is manufactured by growing a metal (Al or Ga) polarity nitride seed layer 12 on an initial growth substrate 11, bonding a primary support substrate 14 on the seed layer 12 through a first bonding layer 13, removing the initial growth substrate 11, bonding a secondary support substrate 16 on a surface from which the initial growth substrate 11 is removed through a second bonding layer 15, and removing the primary support substrate 14.

The corresponding process is a group III nitride epitaxy growth method that has already been widely verified and has an advantage of having high-quality crystallinity and very low surface roughness, making it easy to secure a mirror-like surface, but there are disadvantages such as a low yield due to two-step substrate bonding and high process costs.

Meanwhile, as shown in FIG. 2, in the conventional one-step substrate bonding process, a semiconductor template having a group III metal polar surface is manufactured by growing a nitrogen polarity nitride seed layer 22 on an initial growth substrate 21, bonding a support substrate 24 on the seed layer 22 through a bonding layer 23, and removing the initial growth substrate 21.

The corresponding process has an advantage of increasing a yield and reducing process costs due to the one-step substrate bonding, but in reality, there are disadvantages that it is difficult to grow the seed layer 22 having a nitrogen polar surface with high-quality crystallinity and it is difficult to secure a mirror-like surface due to high surface roughness.

In addition, AlxGa1-xN generally strongly tends to grow to physically have a metal polar state during growth. Due to the physical properties, AlxGa1-xN has a mixed polar form with mixed metal polarity despite trying to grow a nitrogen-polar AlxGa1-xN, and thus a surface roughness issue, such as hillocks, occurs on a surface.

To solve the problem of increased surface roughness due to the occurrence of hillocks and the like, there are a method of changing an off angle of an initial growth substrate and a method of adopting a chemical-mechanical polishing (CMP) process using the easily etched property of a non-polar surface, but when an off angle substrate is used or the CMP process is introduced, there is a problem that process costs significantly increase.

### DISCLOSURE

### Technical Problem

The present invention is intended to solve the above-described conventional problems and is directed to providing a method of manufacturing a high-quality semiconductor template having a group III metal polar surface, which has excellent crystallinity, using only a one-step substrate bonding process.

### Technical Solution

According to the present invention, the above object is achieved by a method of manufacturing a semiconductor template having a group III metal polar surface, which includes a first growing operation of growing a first semiconductor layer having a metal polar surface on a growth substrate, a layer forming operation of forming a polarity inversion layer on the first semiconductor layer, a second growing operation of growing a second semiconductor layer having a nitrogen polar surface on the polarity inversion layer, a bonding operation of bonding the second semiconductor layer and a support substrate, a separating operation of separating the growth substrate, and a removing operation of removing the first semiconductor layer and the polarity inversion layer to expose a metal polar surface of the second semiconductor layer.

In addition, the method of the present invention may further include a re-growing operation of re-growing a device layer on the second semiconductor layer of which the metal polar surface is exposed.

In addition, each of the first semiconductor layer and the second semiconductor layer may be made of AlxGa1-xN.

In addition, the polarity inversion layer may be made of a compound including magnesium (Mg) and nitrogen (N).

According to the present invention, the above object is achieved by a method of manufacturing a semiconductor template having a group III metal polar surface, which includes a first growing operation of growing a first semiconductor layer having a metal polar surface on a growth substrate, a first layer forming operation of forming a first polarity inversion layer on the first semiconductor layer, a second growing operation of growing a second semiconductor layer having a nitrogen polar surface on the first polarity inversion layer, a second layer forming operation of forming a second polarity inversion layer on the second semiconductor layer, a third growing operation of growing a third semiconductor layer having a metal polar surface on the second polarity inversion layer, a bonding operation of bonding the third semiconductor layer and a support substrate, a separating operation of separating the growth substrate, and a removing operation of removing the first semiconductor layer and the first polarity inversion layer to expose a metal polar surface of the second semiconductor layer.

In addition, the method of the present invention may further include a re-growing operation of re-growing a device layer on the second semiconductor layer of which the metal polar surface is exposed.

In addition, each of the first semiconductor layer, the second semiconductor layer, and the third semiconductor layer may be made of AlxGa1-xN.

In addition, the first polarity inversion layer may be made of a compound including magnesium (Mg) and nitrogen (N), and the second polarity inversion layer may be made of a compound including aluminum (Al) and nitrogen (N).

### Advantageous Effects

According to the present invention, a high-quality semiconductor template having a group III metal polar surface, which has excellent crystallinity, using only a one-step substrate bonding process, can be manufactured by selectively growing AlxGa1-xN materials having different polarities on a nominal on-axis c-plane sapphire substrate or an Si(111) initial growth substrate without using an expensive off angle sapphire substrate.

Meanwhile, the effects of the present invention are not limited to the above-described effects, and may include various effects within a range that is apparent to those skilled in the art from the following descriptions.

### DESCRIPTION OF DRAWINGS

FIG. 1 shows a process of manufacturing a semiconductor template having a group III metal polar surface through the conventional two-step substrate bonding process.

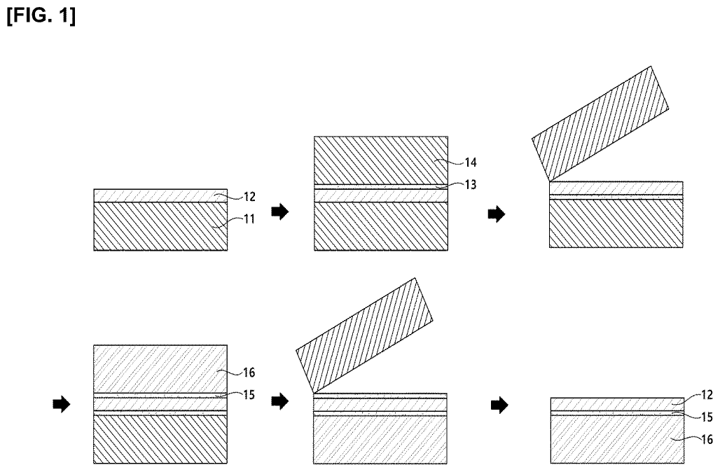

FIG. 2 shows a process of manufacturing a semiconductor template having a group III metal polar surface through the conventional one-step substrate bonding process.

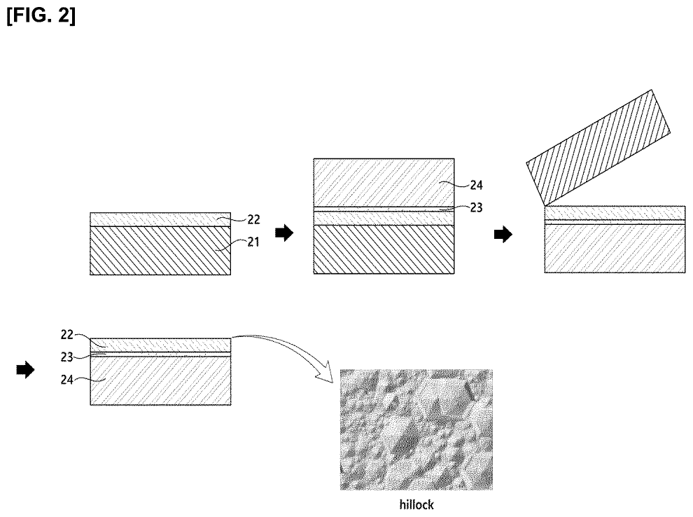

FIG. 3 is a flowchart of a method of manufacturing a semiconductor template having a group III metal polar surface according to a first embodiment of the present invention.

FIG. 4 shows a process of manufacturing a semiconductor template according to the method of manufacturing a semiconductor template having a group III metal polar surface according to the first embodiment of the present invention.

FIG. 5 is a flowchart of a method of manufacturing a semiconductor template having a group III metal polar surface according to a second embodiment of the present invention.

FIG. 6 shows a process of manufacturing a semiconductor template according to the method of manufacturing a semiconductor template having a group III metal polar surface according to the second embodiment of the present invention.

### MODES OF THE INVENTION

Hereinafter, some embodiments of the present invention will be described in detail with reference to exemplary drawings. In adding reference numerals to components in each drawing, it should be noted that the same components have the same reference numerals as much as possible even when they are illustrated in different drawings.

In addition, in describing embodiments of the present invention, detailed descriptions of related known configurations or functions will be omitted when it is determined that the detailed descriptions obscure the understanding of the embodiments of the present invention.

In addition, terms such as first, second, A, B, (a), and (b) may be used to describe components of the embodiments of the present invention. These terms are only for the purpose of distinguishing one component from another component, and the nature, sequence, order, or the like of the corresponding component is not limited by the terms.

The present invention relates to a method of manufacturing a high-quality semiconductor template having a group III metal polar surface, which has excellent crystallinity, using only a one-step substrate bonding process by selectively growing AlxGa1-xN materials having different polarities on a nominal on-axis c-plane sapphire substrate or an Si initial growth substrate without using an expensive off angle sapphire substrate.

Hereinafter, a method S100 of manufacturing a semiconductor template having a group III metal polar surface according to the first embodiment of the present invention will be described in detail with reference to the accompanying drawings.

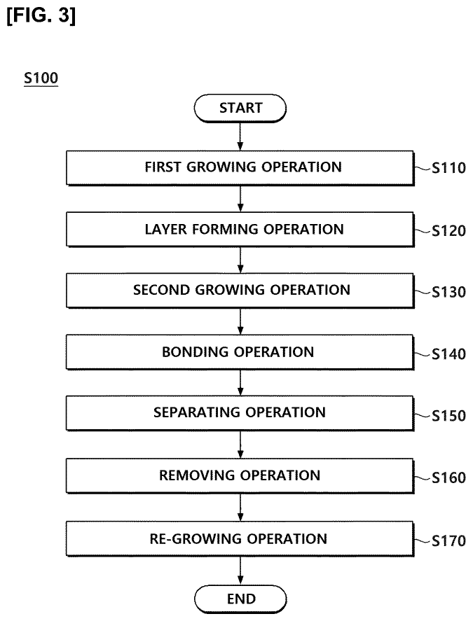

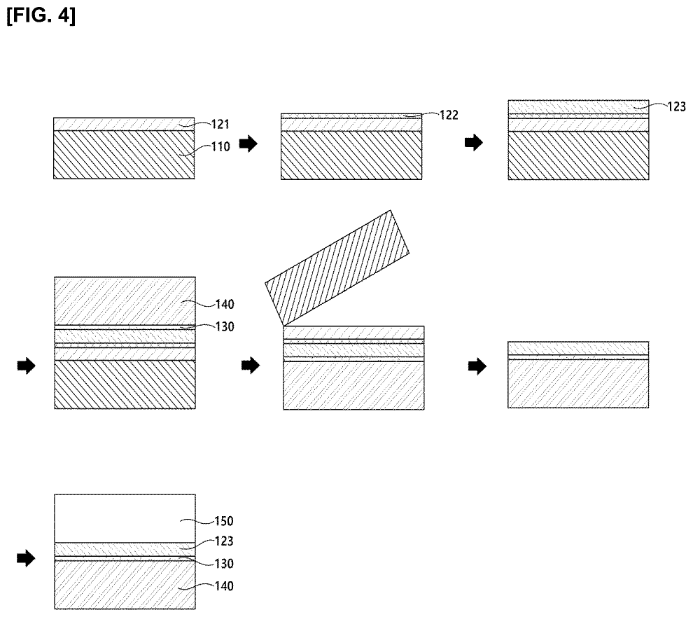

FIG. 3 is a flowchart of a method of manufacturing a semiconductor template having a group III metal polar surface according to a first embodiment of the present invention, and FIG. 4 shows a process of manufacturing a semiconductor template according to the method of manufacturing a semiconductor template having a group III metal polar surface according to the first embodiment of the present invention.

As shown in FIGS. 3 and 4, the method S100 of manufacturing a semiconductor template having a group III metal polar surface according to the first embodiment of the present invention includes a first growing operation S110, a layer forming operation S120, a second growing operation S130, a bonding operation S140, a separating operation S150, a removing operation S160, and a re-growing operation S170.

The first growing operation S110 and the second growing operation S130 of the present invention are operations of growing AlGaN having different surface polarities on a heterogeneous initial growth substrate 110, and first, the first growing operation S110 is an operation of growing a first semiconductor layer 121 having a group III metal polar surface on the initial growth substrate 110.

The initial growth substrate 110 may be provided as a sapphire substrate or an Si substrate (nominal on-axis c-plane), and when the initial growth substrate 110 is removed through a laser lift off (LLO) technique in the separating operation S150 to be described below, the initial growth substrate 110 is preferably provided as an optically transparent and high-temperature heat-resistant sapphire substrate that can transmit 100% (theoretically) of a laser beam (single wavelength light) without absorption, and the initial growth substrate 110 is also preferably provided as a patterned sapphire substrate (PSS) having a protrusion shape that is regularly or irregularly patterned in various dimensions (size and shape) in microscale or nanoscale in order to minimize crystal defects inside a group III nitride semiconductor thin film grown on the initial growth substrate 110.

Meanwhile, when the initial growth substrate 110 is removed through a chemical lift off (CLO) technique in the separating operation S150 to be described below, the initial growth substrate 110 is preferably provided as an Si substrate that may be removed by wet etching, mechanically polished, and selectively etched, and the Si substrate may be made of Si having a (111) crystal face so that a high-quality group III nitride semiconductor thin film may be grown.

In the first growing operation S110, the first semiconductor layer 121 having a group III metal polar surface may be grown on the initial growth substrate 110, and in this case, the first semiconductor layer 121 may be made of AlxGa1-xN and may have a thickness of about 1.5 μm.

The layer forming operation S120 is an operation of forming a polarity inversion layer 122 on the first semiconductor layer 121. The polarity inversion layer 122 inverts a surface polarity of a second semiconductor layer 123 to be grown later to nitrogen polar, may be made of a nitride (MgxN2) containing magnesium (Mg) or a nitride (MgxSiyN2) containing magnesium (Mg) and silicon (Si) through a continuous subsequent in-situ MOCVD process after the first semiconductor layer 121 is grown, and may have a thickness of about 0.5 μm to obtain a nitrogen polar second semiconductor layer 123 having a mirror-like surface. Meanwhile, in the layer forming operation S120 of the present invention, the polarity inversion layer 122 may be formed through an ex-situ annealing process under an oxygen (O2) or nitrogen (N2) atmosphere.

The second growing operation S130 is an operation of growing the second semiconductor layer 123 having a nitrogen polar surface on the polarity inversion layer 122. That is, in the second growing operation S130, the second semiconductor layer 123 may be grown to have a nitrogen polar surface through the polarity inversion layer 122, and in this case, the second semiconductor layer 123 may be made of AlxGa1-xN and may have a thickness of about 1.5 μm.

The bonding operation S140 is an operation of bonding the nitrogen polar surface of the second semiconductor layer 123 and a support substrate 140 through a bonding layer 130.

Here, the support substrate 140 is a substrate that supports the second semiconductor layer 123 and a device layer 150 formed on the second semiconductor layer 123 after undergoing each operation of the method S100 of manufacturing a semiconductor template having a group III metal polar surface according to the first embodiment of the present invention, and in the present embodiment, a final support substrate 140 is preferably made of a material that may have high heat dissipation performance (60 W/mk or more), have a coefficient of thermal expansion (CTE) that is the same as or similar to that of the device layer 150, and have a polycrystalline microstructure as a result of high-temperature sintering processing, and the material may include, for example, Si (149 W/mk, 2.6 ppm), SiC (300 to 450 W/mk, 4.8 ppm), AlN (170 to 230 W/mk, 4.5 ppm), SiNx (90 W/mk, 3.7 ppm), sapphire, etc., but is not limited thereto.

In the past, epitaxial wafer bowing occurred due to the thermo-mechanical induced stress caused by differences in lattice constant (LC) and CTE between the initial growth substrate 110 and a group III nitride semiconductor, however, in the present invention, this can be resolved by strongly bonding the support substrate 140 to one surface of the second semiconductor layer 123 through the bonding layer 130. That is, since the epitaxial wafer to which the support substrate 140 is bonded is in a stress-relieved state and wafer bowing can be minimized to almost zero, there is an advantage that this method can be applied to wafers having sizes of not only 4 inches, 6 inches, and 8 inches, but also 12 inches or more.

Meanwhile, in the bonding operation S140, the nitrogen polar surface of the second semiconductor layer 123 may be bonded to the support substrate 140 by forming a first bonding layer 130 on one surface of the second semiconductor layer 123, forming a second bonding layer 130 on the support substrate 140, and then bonding the first bonding layer 130 and the second bonding layer 130.

Here, the bonding layer 130 (including the first bonding layer 130 and the second bonding layer 130) may be preferentially selected from dielectric materials whose properties do not change and which have excellent thermal conductivity in the MOCVD chamber (at a temperature of 1000° C. or higher and in a reducing atmosphere) in which the group III nitride semiconductor is grown, and may contain, for example, SiO2 (0.8 ppm), SiNx (3.7 ppm), SiCN (3.8 to 4.8 ppm), AlN (4.5 ppm), Al2O3 (6.8 ppm), or amorphous Si, and furthermore, may contain a flowable oxide (FOx) such as spin on glass (SOG) (liquid SiO2) or hydrogen silsesquioxane (HSQ) to improve surface roughness. Furthermore, the bonding layer 130 may be made of a metal such as Al, W, or Mo, or an alloy thereof.

Therefore, in the present invention, the second semiconductor layer 123 grown to high quality is bonded with a high heat-resistant bonding material layer on the support substrate 140 having high heat dissipation performance, thereby enabling the single crystalline growth of a high-quality group III nitride semiconductor at a high temperature of 700° C. or higher.

Meanwhile, in the bonding operation S140 of the present invention, a reinforcing layer and the first bonding layer 130 may be sequentially stacked on one surface of the second semiconductor layer 123, a reinforcing layer and the second bonding layer 130 may be sequentially stacked on the support substrate 140, and then the first bonding layer 130 and the second bonding layer 130 may be pressed to form the bonding layer 130.

Here, the reinforcing layer is a layer for reinforcing the bonding strength with the support substrate 140 and inducing compressive stress, and more specifically, the reinforcing layer may include a bonding reinforcing layer and a compressive stress layer.

The bonding reinforcing layer is a layer introduced to increase bonding strength when the second semiconductor layer 123 is bonded on the support substrate 140 through the bonding layer 130, and a material constituting the bonding reinforcing layer is preferably selected from SiO2, SiNx, etc.

The compressive stress layer is made of a dielectric material with a greater CTE than the support substrate 140, for example, a material that relieves tensile stress, that is, induces compressive stress, such as AlN (4.6 ppm), AlNO (4.6 to 6.8 ppm), Al2O3 (6.8 ppm), SiC (4.8 ppm), SiCN (3.8 to 4.8 ppm), GaN (5.6 ppm), or GaNO (5.6 to 6.8 ppm), which serves to guide the quality improvement of products through stress control.

Meanwhile, in the present invention, the bonding reinforcing layer or compressive stress layer may be omitted in some cases, and in some cases, the entire reinforcing layer may be omitted so that one surface of the second semiconductor layer 123 is in direct contact with the bonding layer 130 or the support substrate 140 is in direct contact with the bonding layer 130. This case may be a structure that induces compressive stress together with a bonding function by forming the bonding layer 130 using a material having a greater CTE than the support substrate 140.

The separating operation S150 is an operation of separating the initial growth substrate 110 from the first semiconductor layer 121 using an LLO technique or CLO technique depending on the material of the initial growth substrate 110.

Here, the LLO technique is a technique used when the initial growth substrate 110 is provided as a sapphire substrate and is a technique of separating an epitaxy-grown layer from the initial growth substrate 110 by irradiating a back surface of the transparent initial growth substrate 110 with an ultraviolet (UV) laser beam having a uniform optical output and beam profile, and a single wavelength. When the initial growth substrate 110 is separated, the insides of the first semiconductor layer 121 and the second semiconductor layer 123 that are transferred onto the support substrate 140 are in a state in which the stress has been completely relieved and maintain a flat state together with the support substrate 140.

In addition, the CLO technique is a technique used when the initial growth substrate 110 is provided as an Si substrate and is a technique of separating and removing an Si material of the initial growth substrate 110 through wet etching using a tetramethylammonium hydroxide (TMAH) or hydrofluoric+nitric+acetic acids (HNA) solution to completely remove the remaining thin Si after mechanically grinding and polishing the back surface of the Si initial growth substrate 110 having a (111) crystal face. When the initial growth substrate 110 is separated, the insides of the first semiconductor layer 121 and the second semiconductor layer 123 that are transferred onto the support substrate 140 are in a state in which the stress has been completely relieved and maintain a flat state together with the support substrate 140. Meanwhile, before removing the residual Si material after mechanically grinding and polishing the initial growth substrate 110, the initial growth substrate 110 is preferably protected from an etchant by forming a protective film such as SiO2 or SiNx on a back surface of the support substrate 140.

The removing operation S160 is an operation of removing the first semiconductor layer 121 and the polarity inversion layer 122 to expose the group III metal polar surface of the second semiconductor layer 123.

More specifically, the removing operation S160 is an operation of completely removing the first semiconductor layer 121 remaining after separating the initial growth substrate 110, and in this case, since an externally exposed surface of the first semiconductor layer 121 has a nitrogen polarity, the above surface may be easily decomposed through a chemical reaction in a base or basic salt solution, and the polarity inversion layer 122 may also be easily removed through a chemical reaction.

Then, since a surface of the second semiconductor layer 123 that is exposed externally after the first semiconductor layer 121 and the polarity inversion layer 122 are removed has a metal polarity, the above surface functions as an etching stop film that does not undergo a chemical reaction even in a base or basic salt solution, and a mirror-like surface may be obtained without an additional CMP process.

The re-growing operation S170 is an operation of re-growing a high-quality group III nitride-based device layer 150 on the second semiconductor layer 123 of which the group III metal polar surface is exposed.

That is, in the re-growing operation S170, a high-quality group III nitride-based device layer 150 for a power semiconductor device such as an HEMT, a light emitting element such as a light emitting diode (LED), or a communication filter device is re-grown using MOCVD.

Hereinafter, a method S200 of manufacturing a semiconductor template having a group III metal polar surface according to the second embodiment of the present invention will be described in detail with reference to the accompanying drawings.

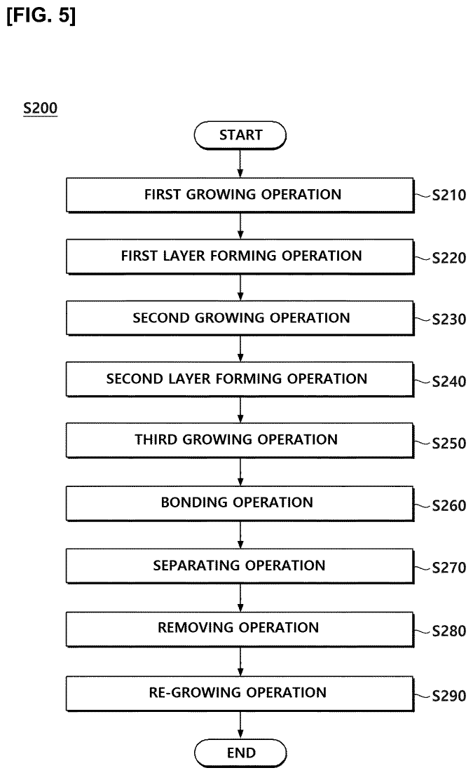

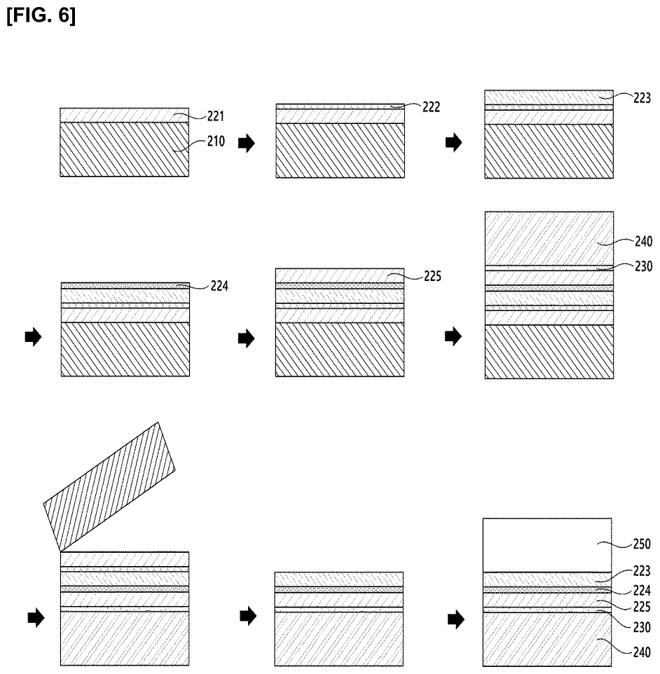

FIG. 5 is a flowchart of a method of manufacturing a semiconductor template having a group III metal polar surface according to a second embodiment of the present invention, and FIG. 6 shows a process of manufacturing a semiconductor template according to the method of manufacturing a semiconductor template having a group III metal polar surface according to the second embodiment of the present invention.

As shown in FIGS. 5 and 6, the method S200 of manufacturing a semiconductor template having a group III metal polar surface according to the second embodiment of the present invention includes a first growing operation S210, a first layer forming operation S220, a second growing operation S230, a second layer forming operation S240, a third growing operation S250, a bonding operation S260, a separating operation S270, a removing operation S280, and a re-growing operation S290.

The first growing operation S210, the second growing operation S230, and the third growing operation S250 of the present invention are operations of growing AlGaN having different surface polarities on a heterogeneous initial growth substrate 210, and first, the first growing operation S210 is an operation of growing a first semiconductor layer 221 having a group III metal polar surface on the initial growth substrate 210.

Since the following description of the first growing operation S210 is the same as the above-described method of manufacturing a semiconductor template having a group III metal polar surface according to the first embodiment of the present invention, overlapping descriptions thereof will be omitted.

The first layer forming operation S220 is an operation of forming a first polarity inversion layer 222 on the first semiconductor layer 221. The first polarity inversion layer 222 inverts a surface polarity of a second semiconductor layer 223 to be grown later to nitrogen polar, may be made of a nitride (MgxN2) containing magnesium (Mg) or a nitride (MgxSiyN2) containing magnesium (Mg) and silicon (Si) through a continuous subsequent in-situ MOCVD process after the first semiconductor layer 221 is grown, and may have a thickness of about 0.5 μm to obtain a nitrogen polar second semiconductor layer 223 having a mirror-like surface. Meanwhile, in the first layer forming operation S220 of the present invention, the first polarity inversion layer 222 may be formed through an ex-situ annealing process under an oxygen (O2) or nitrogen (N2) atmosphere.

The second growing operation S230 is an operation of growing the second semiconductor layer 223 having a nitrogen polar surface on the first polarity inversion layer 222. That is, in the second growing operation S230, the second semiconductor layer 223 may be grown to have a nitrogen polar surface through the first polarity inversion layer 222, and in this case, the second semiconductor layer 223 may be made of AlxGa1-xN and may have a thickness of about 1.5 μm.

The second layer forming operation S240 is an operation of forming a second polarity inversion layer 224 on the second semiconductor layer 223. The second polarity inversion layer 224 inverts a surface polarity of a third semiconductor layer 225 to be grown later to metal polar and may be made of a compound containing aluminum (Al) and nitrogen (N), and specifically, the second polarity inversion layer 224 may be formed by performing preprocessing (trimethylaluminum (TMAl) or triethylaluminum (TEAl) preflow) using an aluminum source through a continuous subsequent in-situ MOCVD process or forming an AlN or AlON interlayer through an ex-situ PVD (sputtering or E-beam).

The third growing operation S250 is an operation of growing the third semiconductor layer 225 having a nitrogen polar surface on the second polarity inversion layer 224. That is, in the third growing operation S250, the third semiconductor layer 225 may be grown to have a metal polar surface through the second polarity inversion layer 224, and in this case, the third semiconductor layer 225 may be made of AlxGa1-xN and may have a thickness of about 1.5 μm.

The bonding operation S260 is an operation of bonding the metal polar surface of the third semiconductor layer 225 and a support substrate 240 through a bonding layer 230.

Here, the support substrate 240 is a substrate that supports the third semiconductor layer 225, the second semiconductor layer 223, and a device layer 250 formed on the second semiconductor layer 223 after undergoing each operation of the method S200 of manufacturing a semiconductor template having a group III metal polar surface according to the second embodiment of the present invention, and in the bonding operation S260, the metal polar surface of the third semiconductor layer 225 may be bonded to the support substrate 240 by forming a first bonding layer 230 on one surface of the support substrate 240, forming a second bonding layer 230 on the support substrate 240, and then bonding the first bonding layer 230 and the second bonding layer 230. Meanwhile, in the bonding operation S260, a reinforcing layer and the first bonding layer 230 may be sequentially stacked on one surface of the third semiconductor layer 225, a reinforcing layer and the second bonding layer 230 may be sequentially stacked on the support substrate 240, and then the first bonding layer 230 and the second bonding layer 230 may be pressed to form the bonding layer 230.

Since the following description of the bonding operation S260 is the same as the above-described method of manufacturing a semiconductor template having a group III metal polar surface according to the first embodiment of the present invention, overlapping descriptions thereof will be omitted.

The separating operation S270 is an operation of separating the initial growth substrate 210 from the first semiconductor layer 221 using an LLO technique or CLO technique depending on the material of the initial growth substrate 210.

Since the following description of the separating operation S270 is the same as the above-described method of manufacturing a semiconductor template having a group III metal polar surface according to the first embodiment of the present invention, overlapping descriptions thereof will be omitted.

The removing operation S280 is an operation of removing the first semiconductor layer 221 and the first polarity inversion layer 222 to expose the metal polar surface of the second semiconductor layer 223.

More specifically, the removing operation S280 is an operation of completely removing the first semiconductor layer 221 remaining after separating the initial growth substrate 210, and in this case, since an externally exposed surface of the first semiconductor layer 221 has a nitrogen polarity, the above surface may be easily decomposed through a chemical reaction in a base or basic salt solution, and the first polarity inversion layer 222 may also be easily removed through a chemical reaction.

Then, since a surface of the second semiconductor layer 223 that is exposed externally after the first semiconductor layer 221 and the first polarity inversion layer 222 are removed has a metal polarity, the above surface functions as an etching stop film that does not undergo a chemical reaction even in a base or basic salt solution, and a mirror-like surface may be obtained without an additional CMP process.

The re-growing operation S290 is an operation of re-growing a high-quality group III nitride-based device layer 250 on the second semiconductor layer 223 of which the group III metal polar surface is exposed.

That is, in the re-growing operation S290, a high-quality group III nitride-based device layer 250 for a power semiconductor device such as an HEMT, a light emitting element such as a light emitting diode (LED), or a communication filter device is re-grown using MOCVD.

As described above, although all the components constituting embodiments of the present invention are described as being combined or combined to operate as one, the present invention is not necessarily limited to these embodiments. That is, one or more of all the components may be combined to operate as one without departing from the scope of the purpose of the present invention.

In addition, the term such as “comprise,” “constitute,” or “have” described above means that the corresponding component can be included unless otherwise stated, and thus should be construed as further including another component rather than excluding another component. All terms including technical or scientific terms have the same meaning as commonly understood by those skilled in the art to which the present invention pertains unless defined otherwise. Commonly used terms, such as terms defined in a dictionaries, should be interpreted as being consistent with the contextual meaning of the related art and are not interpreted in an ideal or excessively formal meaning unless explicitly defined herein.

In addition, the above description is merely an exemplary description of the technical spirit of the present invention, and those skilled in the art to which the present invention pertains will be able to variously modify and change the present invention without departing from the essential characteristics of the present invention.

Therefore, embodiments disclosed in the present invention are not intended to limit the technical spirit of the present invention, but intended to describe the same, and the scope of the technical spirit of the present invention is not limited by these embodiments. The scope of the present invention should be construed by the appended claims, and all technical ideas within the equivalent scope should be construed as being included in the scope of the present invention.

1. A method of manufacturing a semiconductor template having a group III metal polar surface, the method comprising:
a first growing operation of growing a first semiconductor layer having a metal polar surface on a growth substrate;
a layer forming operation of forming a polarity inversion layer on the first semiconductor layer:
a second growing operation of growing a second semiconductor layer having a nitrogen polar surface on the polarity inversion layer;
a bonding operation of bonding the second semiconductor layer and a support substrate;
a separating operation of separating the growth substrate; and
a removing operation of removing the first semiconductor layer and the polarity inversion layer to expose a metal polar surface of the second semiconductor layer.

2. The method of claim 1, further comprising a re-growing operation of re-growing a device layer on the second semiconductor layer of which the metal polar surface is exposed.

3. The method of claim 1, wherein each of the first semiconductor layer and the second semiconductor layer is made of AlₓGa₁₋ₓN.

4. The method of claim 1, wherein the polarity inversion layer is made of a compound including magnesium (Mg) and nitrogen (N).

5. A method of manufacturing a semiconductor template having a group III metal polar surface, the method comprising:
a first growing operation of growing a first semiconductor layer having a metal polar surface on a growth substrate;
a first layer forming operation of forming a first polarity inversion layer on the first semiconductor layer:
a second growing operation of growing a second semiconductor layer having a nitrogen polar surface on the first polarity inversion layer;
a second layer forming operation of forming a second polarity inversion layer on the second semiconductor layer:
a third growing operation of growing a third semiconductor layer having a metal polar surface on the second polarity inversion layer;
a bonding operation of bonding the third semiconductor layer and a support substrate;
a separating operation of separating the growth substrate; and
a removing operation of removing the first semiconductor layer and the first polarity inversion layer to expose a metal polar surface of the second semiconductor layer.

6. The method of claim 5, further comprising a re-growing operation of re-growing a device layer on the second semiconductor layer of which the metal polar surface is exposed.

7. The method of claim 5, wherein each of the first semiconductor layer, the second semiconductor layer, and the third semiconductor layer is made of AlₓGa₁₋ₓN.

8. The method of claim 5, wherein the first polarity inversion layer is made of a compound including magnesium (Mg) and nitrogen (N), and
the second polarity inversion layer is made of a compound including aluminum (Al) and nitrogen (N).
